(19) United States
(12) Patent Application Publication
(10) Pub. No.: US 2009/0067246 A1
(43) Pub. Date: Mar. 12, 2009

(54) Methods to Prevent Program Disturb in Nonvolatile Memory

(76) Inventor: Andrew J. Walker, Mountain View, CA (US)

Correspondence Address: MACPHERSON KWOK CHEN & HEID LLP, 2033 GATEWAY PLACE, SUITE 400, SAN JOSE, CA, 95110, US

(21) Appl. No.: 12/208,259

(22) Filed: Sep. 10, 2008

Related U.S. Application Data
(60) Provisional application No. 60/971,711, filed on Sep. 12, 2007.

(51) Int. Cl. G11C 16/04; G11C 16/06

(52) U.S. Cl. 365/185.17; 365/185.19; 365/185.18

(57) ABSTRACT

Methods are provided to be used individually or in any combination that reduce program disturb in a non-volatile memory consisting of dual-gate memory cells. These methods counteract the effect of a leakage current in reducing a boosted voltage in a non-selected dual-gate memory string. According to one approach, a voltage applied to the gate electrode of an access device of a dual-gate memory cell is increased during a programming event. According to a second approach, the gate electrodes of an access device of a dual-gate memory cell is applied a series of electrical pulses synchronously with programming the memory device of the dual-gate memory cell by a second series of electrical pulses. According to a third approach, multiple dual-gate select devices are provided between a string of dual-gate memory devices and either a source line or a bit line, or both.

### CROSS-REFERENCE TO RELATED APPLICATIONS

The present patent application is related to and claims priority of U.S. provisional patent application (“Provisional Application”), entitled “Methods to Prevent Program Disturb in Nonvolatile Memory,” Ser. No. 60/971,711, which was filed on Sep. 12, 2007. The present patent application is also related to U.S. patent application (“Copending Application”), entitled “Nonvolatile Memory and Method of Program Inhibition,” Ser. No. 11/304,231, filed on Dec. 14, 2005.

The Provisional Application and the Copending Application are hereby incorporated herein by reference in their entireties.

### BACKGROUND OF THE INVENTION

1. Field of the Invention

The present invention relates to program inhibition methods in non-volatile memories. In particular, the present invention relates to program inhibition methods in dual-gate memory strings.

2. Discussion of the Related Art

Dual-gate devices are used in high density integrated circuits (e.g., non-volatile memories). Examples of dual-gate devices and their use are found described, for example, in the Copending Application incorporated by reference above. In this context, for example, a NAND-type dual-gate memory string includes serially-connected dual-gate memory cells, with each memory cell consisting of a non-memory device (also referred to as an “access device”) and a memory device formed on a common active semiconductor region, sharing source and drain regions.

Methods for avoiding inadvertent programming of cells in a NAND-type memory string can be found in the literature, such as:

(a) The article “A 3.3V 32 Mb NAND Flash Memory with Incremental Step Pulse Programming Scheme” (“Suh”) by Suh et al., published in IEEE J. Solid-State Circuits, vol. 30, pp. 1149-1156, November 1995. Suh discloses capacitance boosting (also referred to as “self-boosting”) of an inversion channel in a cell of a non-selected NAND string. Using capacitance boosting, programming is inhibited in the cell of a non-selected NAND string that shares a programming voltage on a word line (i.e., gate electrode) with the cell to be programmed in a selected NAND string.

(b) The article “A 117-mm2 3.3-V Only 128-Mb Multilevel NAND Flash Memory for Mass Storage Applications” *(“Jung”) by Jung et al., published in IEEE J. Solid-State Circuits, vol. 31, pp. 1575-1583, November 1996. Jung discloses extra capacitance boosting (also referred to as “local self-boosting”) of an inversion channel of a cell in a non-selected string that shares a programming voltage on its word line (i.e., gate electrode) with a cell to be programmed in the selected NAND string. In this instance, the inversion channel of the cell in the non-selected string is isolated from the other inversion channels in the non-selected string.

(c) U.S. Pat. No. 5,991,202, entitled “Method for reducing Program Disturb during Self-Boosting in a NAND Flash Memory” (“Derhacobian”) to Derhacobian et al, which was filed on Sep. 24, 1998. Derhacobian discloses a method for reducing program disturb in a non-selected NAND string through more efficient capacitance boosting in the presence of a leakage current. Such a leakage current may reduce the boosted voltage in the inversion layer in the non-selected NAND string. Derhacobian's method applies the program voltage and the program pass voltage using a series of pulses, instead of a single pulse.

(d) U.S. Pat. No. 7,023,739, entitled “NAND Memory Array Incorporating Multiple Write Pulse Programming of Individual Memory Cells and Method for Operation of Same” (“Chen”) to Chen et al., which was filed on Dec. 5, 2003. Chen discloses methods for program inhibition in NAND strings made up of single-gate thin-film transistors, where a leakage current would reduce the boosted voltage of an inversion layer in a non-selected NAND string. Chen's methods involve pulsed applications of the program voltage and program pass voltage to the word lines of the single-gated memory devices. Chen also teaches using more than one serially-connected single-gated transistor as select devices between the NAND string and a source or bit line node.

Other documents relevant to the subject matter include: (a) the article “Leakage Current Modeling of Series-Connected Thin Film Transistors” (“Sturm”), by Sturm et al., published in IEEE Transactions on Electron Devices, vol. 42, pp. 1561-1563, August 1995; and (b) the article “Development and Electrical Properties of Undoped Polycrystalline Silicon Thin-Film Transistors” (“Proano”) by Proano et al., published in IEEE Transactions on Electron Devices, vol. 36, pp. 1915-1922, September 1989.

### SUMMARY

According to one embodiment of the present invention, techniques are disclosed for preventing program disturb in a dual-gate memory cell of a non-selected memory string. The memory cell in the non-selected memory string shares a word line with a corresponding memory cell in a selected string which is to be programmed. The disclosed techniques are applicable in any combination or singly to minimize program disturb. The techniques include:
(a) during programming, increasing the program pass voltage (e.g., using voltage ramps or voltage steps) applied on the gate electrodes of access devices, to counteract a droop in boosted voltage due to a leakage current in the non-selected dual-gate memory string;
(b) in a non-selected dual-gate memory string, pulsing a program pass voltage on the gate electrodes of the access device of a dual-gate memory cell synchronously with pulsing a program voltage on the gate electrode of the memory device of the dual-gate memory cell, so as to reduce the effect of a droop in the boosted voltage due to a leakage current; and
(c) Using multiple serially-connected dual-gate devices as select devices between the dual-gate memory string and the source connection.

In one embodiment, when necessary, multiple dual-gate select devices may also be provided between the memory string and a bit line contact. This dual-gate select devices approach is especially amenable to prevent program disturb, because a channel of a dual gate device can be made thin, while the associated source and drain regions can be made thick, so that-the volume of channel silicon, within which a high field leakage current may originate, can be made small.

The present invention is better understood upon consideration of the detailed description below, in conjunction with the accompanying drawings.

### BRIEF DESCRIPTION OF THE DRAWINGS

FIG. 1 shows dual-gate memory cell 100 to which the present invention is applicable.

FIG. 2 is a circuit representation of a dual-gate memory device.

FIG. 3 is a circuit representation of memory strings 501 and 502 in a memory array.

FIG. 4 shows cross sections of dual-gate memory strings 501 and 502 of FIG. 3.

FIG. 5 is a cross section of non-selected string 502, further showing inversion channels in the access devices leading to the memory cell that is to be program-inhibited.

FIG. 6 is a cross section of a dual-gate memory cell in non-selected string 502, showing inversion channels in the memory and access devices of the dual-gate memory cell.

FIG. 7 shows an example of the voltages applied to the memory strings 501 and 502 of FIGS. 3 and 4.

FIG. 8 shows applying a program pass voltage to the gate electrodes of the access devices as pulses synchronously with applying the programming voltage as pulses to the gate electrode of the memory device.

FIG. 9 illustrates an example in which three dual-gate select devices 903-905 are provided between the memory cells 901-902 and source node 906.

FIG. 10 is an electron micrograph showing a dual-gate memory string fabricated using sub-100 nm design rules.

To facilitate cross-reference among the figures, like features are assigned like reference numerals.

### DETAILED DESCRIPTION OF THE PREFERRED EMBODIMENT

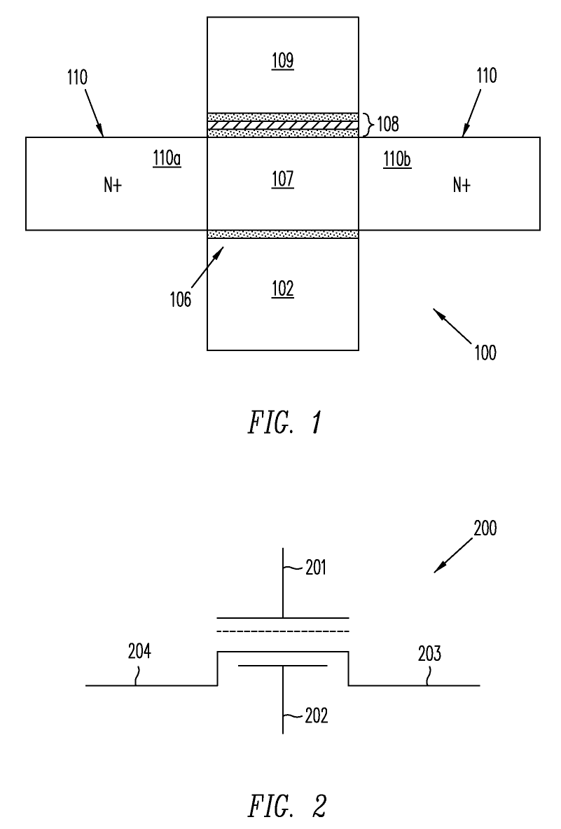

The present invention avoids inadvertently programming of a memory cell of an unselected dual-gate memory string (e.g., a memory string made up of serially-connected dual-gate memory cells). FIG. 1 provides an example of dual-gate memory cell 100, to which the present invention is applicable. As shown in FIG. 1, dual-gate memory cell 100 includes channel region 107, memory dielectric stack 100, word line 109 (i.e., the gate electrode of the memory device), and word line 102 (i.e., the gate electrode of the access device), gate dielectric 106 of the access device, and source and drain regions 110a and 110b, common to both the access device and the memory device. Gate dielectric 106 may be provided by thermally grown or deposited silicon dioxide, or a combination of the two. Charge-storing memory dielectric stack 100 may include a silicon dioxide-silicon nitride-silicon dioxide (ONO) stack. Alternatively, silicon oxynitride can be provided within memory dielectric stack 100, or replaces the silicon nitride in the ONO stack. FIG. 2 is a circuit representation of a dual-gate memory cell, in which reference numeral 201 indicates the gate electrode or word line of the memory device, and reference numeral 202 indicates the gate electrode or word line of the access device and reference numerals 203 and 204 indicate the source and drain electrodes.

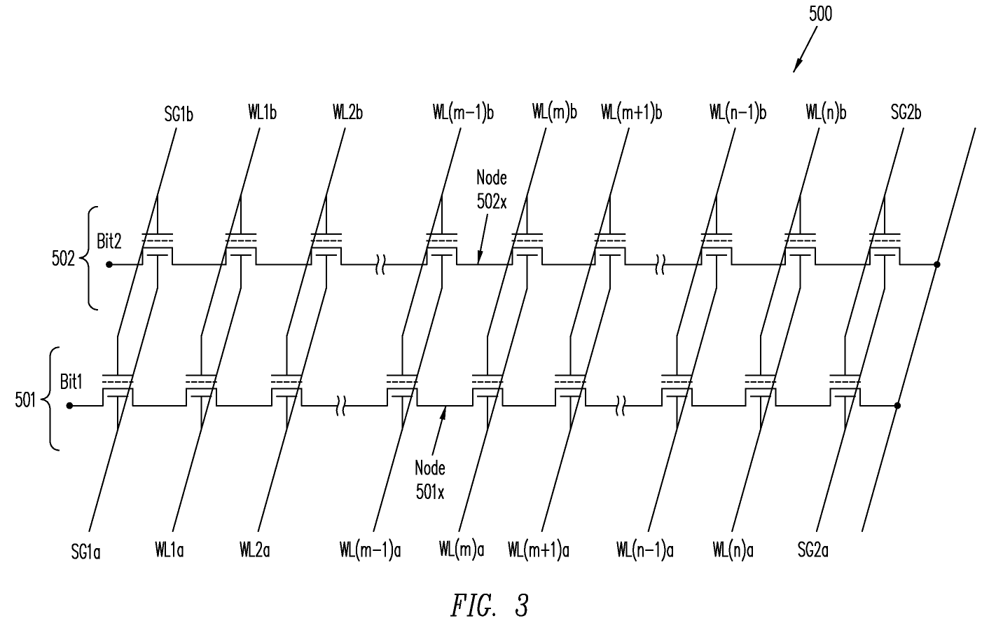

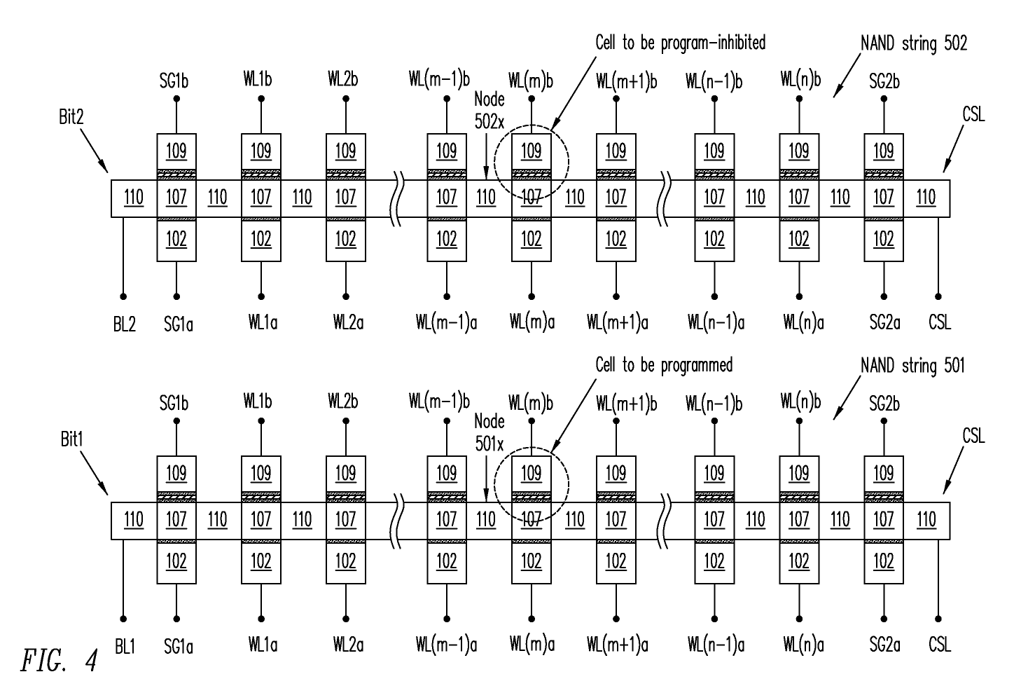

FIG. 3 is a circuit representation of memory strings 501 and 502 in a memory array, with each memory string including a number (n) of serially-connected dual-gate memory cells, select signals (SG1a and SG1b) are provided to control dual-gate select devices in the memory strings, with each dual-gate select device being provided between a bit line contact (Bit1 or Bit2) and the memory cells. Similarly, select signals (SG2a and SG2b) are provided to control dual-gate select devices in the memory strings, with each dual-gate select device being provided between a common source line (CSL) and the memory cells. The dual-gate memory cells in each memory string have the gate electrodes of their access devices connected respectively to word lines WL1a to WL(n)a, and the gate electrodes of their memory devices connected respectively to word lines WL1b to WL(n)b. In FIG. 3, nodes 501x and 502x are identified. To program the memory cell in memory string 501 controlled by word line WL(m)b, node 501x is preferably maintained at close to a ground potential. At the same time, node 502x is boosted in voltage during this programming event, so as to inhibit the corresponding memory cell in non-selected string 502 (i.e., the memory cell that is also controlled by word line WL(m)b) from being inadvertently programmed. To further illustrate, FIG. 4 shows cross sections of dual-gate memory strings 501 and 502 of FIG. 3.

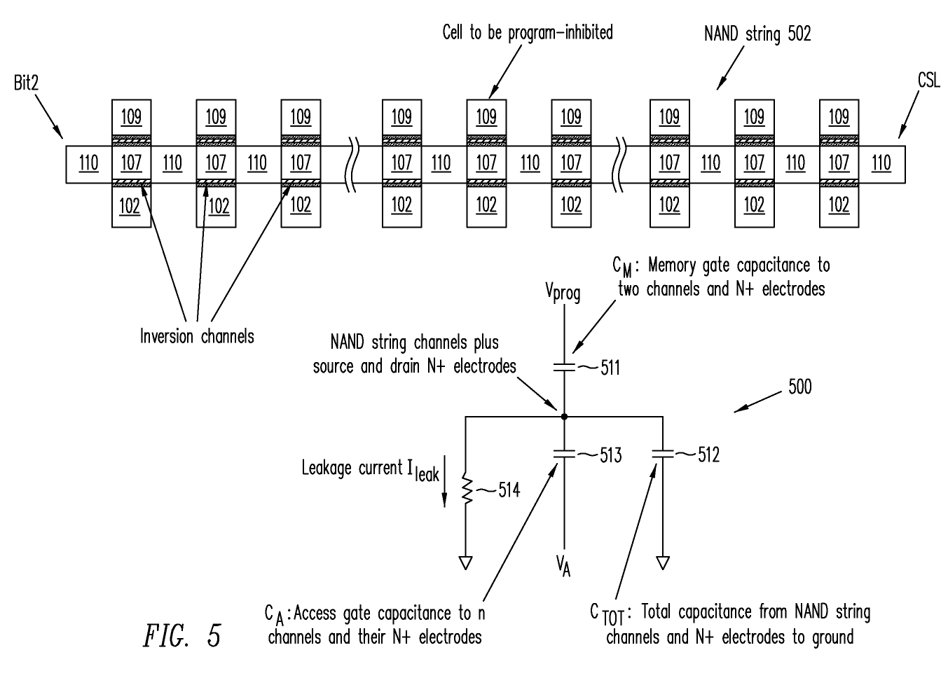

FIG. 5 is a cross section of non-selected string 502, further showing inversion channel regions in the access devices leading to the memory cell that is to be program-inhibited. Also shown in FIG. 5 is equivalent circuit 500 of non-selected string 502. Equivalent circuit 500 includes resistance 514, and capacitors 511, 512 and 513. Resistor 514 models a leakage current in memory string 502 which flows to ground. Capacitor 511 represents capacitance CM between the gate electrode of the memory device and the combined electrical node of the inversion channels and the source and drain regions of the NAND string. Capacitor 512 represents total capacitance C_{TOT} between ground and the combined electrical node of the inversion channels and the source and drain regions of the NAND string. Capacitor 513 represents capacitance C_{A} between the gate electrode of the access device and the combined electrical node of the inversion channels and the source and drain regions of the NAND string. Leakage current Iₗₑₐₖ causes a droop in a boosted voltage at the common node of the capacitors when the program pass voltage V_{A} is applied to the access device.

Capacitors 511-513 are described in the Copending Application incorporated by reference above. Program inhibition is accomplished by boosting the voltage at the common active semiconductor region of the dual-gate memory cell that shares word lines with the selected dual-gate memory cell that is being programmed. With the application of a voltage V_{A} to the access devices and a voltage V_{prog} to the memory device to be inhibited, the voltage V_{ch} of the channel region within the memory cell of the non-selected dual-gate memory string is given by:

$${V}_{ch} = {V}_{chi} + \frac{{C}_{A} \cdot {V}_{A}}{{C}_{A} + {C}_{TOT}} + \frac{{C}_{M} \cdot {V}_{prog}}{{C}_{M} + {C}_{TOT}} - \frac{{I}_{leak} \cdot {T}_{P}}{{C}_{TOT}} \qquad ( 1 )$$

Therefore, according to equation (1), a leakage current from the boosted channel to a region at a lower voltage drags down the boosted voltage. If this drag is sufficiently large, the memory cell in the non-selected memory string may be inadvertently programmed.

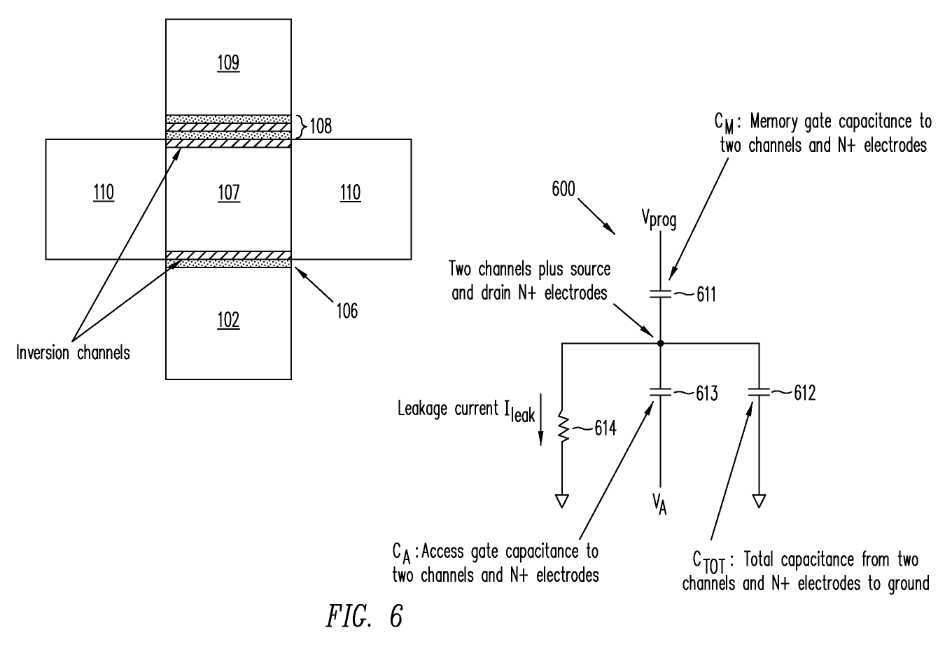

FIG. 6 is a cross section of a dual-gate memory cell in non-selected string 502, showing inversion channels in the memory device and the access device of the dual-gate memory cell. The memory device of the dual-gate memory cell is to be inhibited. Also shown in FIG. 6 is equivalent circuit 600 of non-selected memory string 502 under a self-boosting approach. Equivalent circuit 500 includes resistance 614, and capacitors 611, 612 and 613. Resistor 614 models a leakage current in memory string 502 which flows to ground. Capacitor 611 represents capacitance C_{M} between the gate electrode of the memory device and the combined electrical node of two inversion channels and the source and drain regions of the dual-gate memory cell. Capacitor 612 represents total capacitance C_{TOT} between ground and the combined electrical node of two inversion channels and the source and drain regions of dual-gate memory cell. Capacitor 613 represents capacitance C_{A} between the gate electrode of the access device and the combined electrode of the two channels and the source and drain regions of dual-gate memory cell. Leakage current Iₗₑₐₖ causes a droop in a self-boosted voltage at the common node of the capacitors.

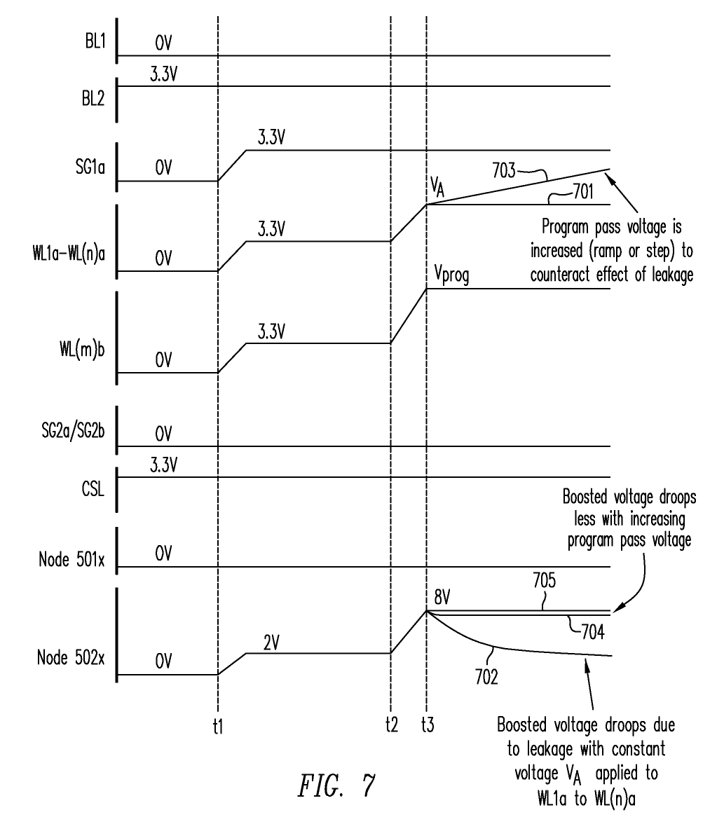

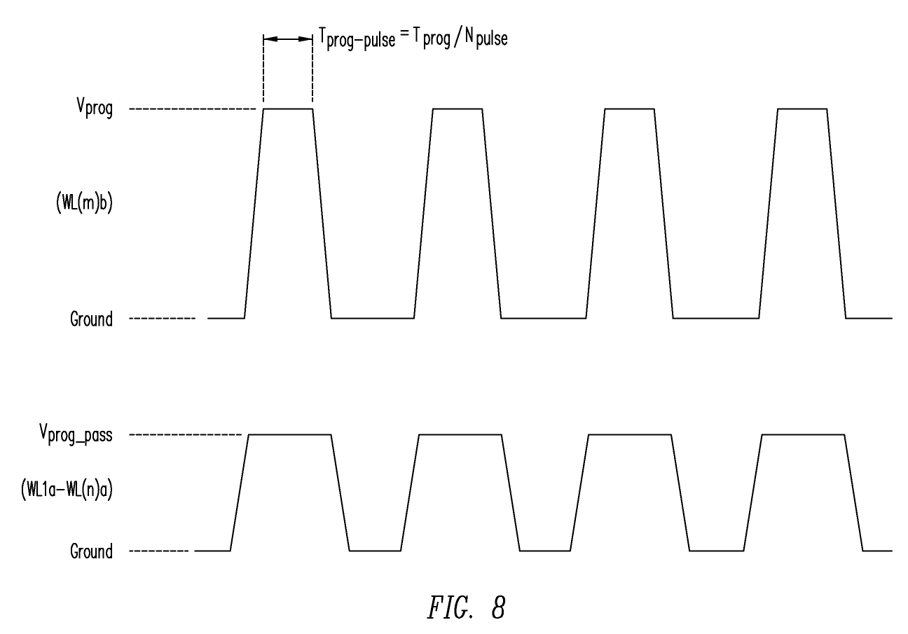

FIG. 7 shows an example of the voltages applied to the memory strings 501 and 502 of FIGS. 3 and 4. As shown in FIG. 7, to program the cell in memory cell 501 associated with word line WL(m)b, (a) bit line BL1 is grounded and bit line BL2 is pulled to 3.3 volts; (b) the select signal SG1a is ramped up to 3.3 volts at time t1; (c) the gate electrodes of the access gates (i.e., word lines WL1a to WL(n)a) are first ramped up to 3.3 volts at time t1, and are further ramped up to program pass voltage V_{A} at time t2 (waveform 701); (d) the gate electrode of the memory cell to be programmed (i.e., word line WL(m)b) is first ramped up to 3.3 volts at time t1, and is further ramped up to program voltage V_{prog} at time t2; (e) the select signals SG2a and SG2b are maintained at ground; and (f) common source line (CSL) is maintained at 3.3 volts. Under this programming procedure, the voltage at node 501x is seen at ground, while the voltage at node 502x is seen first raised to 2.0 volts at time t1, ramped up to 8 volts at time t2, but begins to droop (waveform 702) after reaching 8.0 volts at time t3, which may result in a program disturb condition.

According to one embodiment of the present invention, for a dual-gate memory device in memory string 502, one technique for disturb reduction continues to increase the voltage at the gate electrodes of the access devices (i.e., word lines WL1a-WL(n)a) after the program voltage V_{prog} is applied to the gate electrode of the memory device (i.e., word line WL(m)b), as illustrated by waveform 703. As a result, the voltage at node 502x droops less (waveform 704) as the program pass voltage at the gate electrode of the access device continues to increase after time t3. In fact, when the program pass voltage VA increases at sufficient ramp rate, the voltage at node 502x may be maintained substantially at 8.0 volts after time t3 (waveform 705). In the embodiment shown in FIG. 7, a constant rate of voltage increase (“ramp”) in voltage V_{A} is shown. However, voltage V_{A} may be increased in steps. As illustrated in equation (1), as the leakage current reduces channel voltage V_{ch}, an increase in voltage V_{A} can increase channel voltage V_{ch}.

According to one embodiment of the present invention, a second approach to program disturb reduction uses a pulsed technique to apply the voltages at the word lines (i.e., the voltages at the gate electrodes of the memory and access devices). FIG. 8 shows applying a program pass voltage to the gate electrodes of the access devices (i.e., word lines WL1a to WL(n)a) as pulses synchronously with applying the programming voltage as pulses to the gate electrode of the memory device (i.e., word line WL(m)b). Under this second approach, the voltages applied to the gate electrodes of the select devices, the bit lines and the source nodes may also be pulses, or may be applied continuously during the pulsing of the gate electrodes of the memory and access devices. This second approach alleviates the reduction of the boosted channel voltage by the leakage current. The total exposure to the pulsed program voltage depends on the desired threshold voltage of the memory device.

As discussed above, Derhacobian and Chen report that pulsing techniques can be effective in reducing the effect of a leakage current on a boosted voltage. According to one embodiment of the present invention, the gate electrodes of the access devices are pulsed simultaneously with the memory device to be program-inhibited. This approach is not seen in Derhacobian and Chen, which do not disclose dual-gate memory cells having both memory and non-memory or access devices. According to equation (1), by reducing the time of programming, the effect of the leakage current on the boosted channel voltage is reduced. The total number of pulses to apply is selected such that the selected memory device is programmed to the correct threshold voltage level. Other voltages to the other nodes of FIGS. 3 and 4 (i.e., bit lines BL1, BL2, gate electrodes of select gates SG1a, SG2a, and SG2b, and common source line CSL) may be maintained as described in FIG. 7 throughout this pulsing sequence, may be kept constant throughout the pulsing sequence, or may be pulsed together at the same frequency as the pulses applied to the gate electrodes of the memory and access devices.

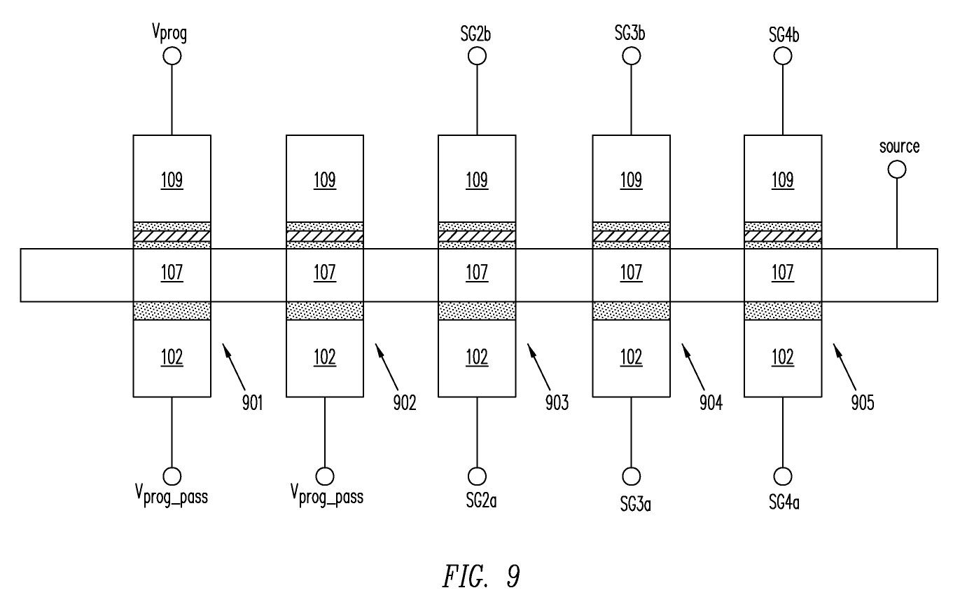

According to one embodiment of the present invention, a third approach for reducing program disturb uses several select devices between the dual-gate memory cells in the memory string and either the source node or the bit line node, or both. During a programming event, such a configuration reduces a leakage current from a boosted electrical node of the non-selected string to the source connection or the bit line connection. FIG. 9 illustrates an example in which three dual-gate select devices 903-905 are provided between the memory cells 901-902 and source node 906. (Although three dual-gate select devices are shown in FIG. 9, more or less select devices may be provided, depending on their combined ability to reduce leakage current between the boosted inversion layer and the source connection. Strum and Proano reported that serially-connection thin-film transistors (TFTs) may reduce leakage current. Chen has used several serially-connected single-gate TFTs to reduce leakage current. Unlike single-gated TFTs, in a dual-gate device, the channel region may be made thin, while the source/drain regions may be made relatively thicker. The source and drain regions are kept in low resistance. This arrangement reduces leakage current, since leakage current is proportional to the volume of channel (within which the high field region occurs). Further, this effect may be magnified using multiple select devices, as shown in FIG. 9.

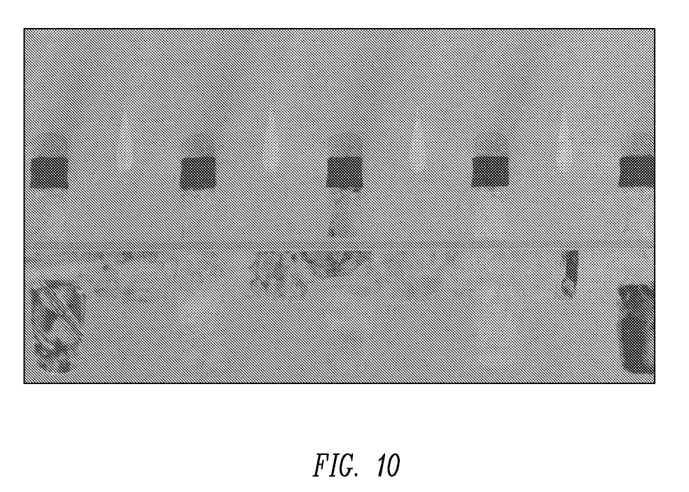

FIG. 10 is a transmission electron micrograph showing a dual-gate memory string fabricated using sub-100 nm design rules. In FIG. 10, the thinner channel between the top and bottom gate electrodes is apparent, while the source and drain regions are seen thicker. Under this multiple select device approach, the voltages on the gate electrodes can be chosen to optimize the leakage reduction. Therefore, the present invention provides the ability to thin the active channel region independently of the source and drain regions, thereby allowing the multiple select device approach to be especially effective in reducing leakage current in a dual-gate device.

The above detailed description is provided to illustrate specific embodiments of the present invention and is not intended to be limiting. Numerous modifications and variations within the scope of the present invention are possible. The present invention is set forth in the accompanying claims.

I claim:

1. A method for preventing loss of a boosted voltage in a dual-gate memory cell including a memory device and an access device sharing a common active semiconductor region, comprising:
bringing the common active semiconductor region to a first voltage above a ground reference;
bringing a gate electrode of the memory device to a second voltage, wherein the voltage difference between the second voltage and the boosted voltage is less than a third voltage and wherein the voltage difference between the second voltage and the ground reference is not less than the third voltage; and
bringing a gate electrode of the access device to a fourth voltage, so as to bring the common active semiconductor region to the boosted voltage, wherein the voltage difference between the fourth voltage and the boosted voltage is not less than a fifth voltage and wherein the fourth voltage is sufficiently high to constrain the boosted voltage at the common active semiconductor region from decreasing greater than a predetermined rate while the gate electrode of the memory device is at the second voltage.

2. A method as in claim 1, wherein third voltage substantially equals a threshold voltage of the memory device.

3. A method as in claim 1, wherein the fifth voltage substantially equals a threshold voltage of the access device.

4. A method as in claim 1, wherein the fourth voltage is an increasing voltage.

5. A method as in claim 4, wherein the fourth voltage comprises a linear increase in voltage.

6. A method as in claim 4, wherein the fourth voltage is comprises one or more step increases in voltage.

7. A method for preventing loss of a boosted voltage in a dual-gate memory cell including a memory device and an access device sharing a common active semiconductor region, comprising:
bringing the common active semiconductor region to a first voltage above a ground reference;
applying a first series of electrical pulses on a gate electrode of the memory device, wherein each electrical pulse of the first series has a voltage peak relative to the ground reference that is not less than a first predetermined voltage; and
applying a second series of electrical pulses on a gate electrode of the access device synchronously with the first series of electrical pulses, wherein each electrical pulse of the second series has a voltage peak relative to the ground reference is not less than a second threshold voltage.

8. A method as in claim 7, wherein the first predetermined voltage substantially equals a threshold voltage of the memory device.

9. A method as in claim 7, wherein the second predetermined voltage substantially equals a threshold voltage of the access device.

10. A method as in claim 9, wherein the dual-gate memory cell is provided in a string of dual-gate memory cells connected between a bit line and a source line, further comprising applying the voltage on the bit line as a third series of electrical pulses synchronously with the first series of electrical pulses.

11. A memory string, comprising:
a plurality of serially-connected select devices; and
a plurality of serially-connected dual-gate memory cells serially connected to the serially-connected select devices.

12. A memory string as in claim 11, wherein the plurality of select devices are connected serially between a bit line and the serially-connected dual-gate memory cells.

13. A memory string as in claim 11, wherein the select devices are connected serially between a source line and the serially-connected dual-gate memory cells.

14. A memory string as in claim 11, wherein each dual-gate memory cell comprises an access device and a memory device.

15. A memory string as in claim 11, wherein each dual-gate memory cell comprises a common active semiconductor region and source and drain regions, and wherein the common active semiconductor region has a thickness less than the thickness of each of the source and drain regions.
